(19) United States
(12) Patent Application Publication
(10) Pub. No.: US 2018/0279494 A1
(43) Pub. Date: Sep. 27, 2018

(54) HOUSING STRUCTURE OF ELECTRONIC DEVICE AND MANUFACTURING METHOD THEREOF

(71) Applicant: Acer Incorporated, New Taipei City (TW)

(72) Inventors: Yi-Mu Chang, New Taipei City (TW); Ching-Piao Kuan, New Taipei City (TW); Wen-Chieh Tai, New Taipei City (TW); Cheng-Nan Ling, New Taipei City (TW)

(73) Assignee: Acer Incorporated, New Taipei City (TW)

(21) Appl. No.: 15/695,015

(22) Filed: Sep. 5, 2017

(30) Foreign Application Priority Data
Mar. 21, 2017 (TW) 106109354

(51) Int. Cl. H05K 5/02; B29C 45/14; G06F 1/16

(52) U.S. Cl. CPC H05K 5/0243; B29C 45/1418; B29L 2031/3481; G06F 1/1656; B29C 2045/14237; G06F 1/1626

(57) ABSTRACT

A housing structure of an electronic device including a transparent housing and an opaque film is provided. The transparent housing has an inner surface and an outer surface opposite to each other, and the transparent housing has at least one opening connecting the inner and the outer surfaces. The opaque film is attached to the inner surface by vacuuming and discharging air out of the opaque film and the transparent housing through the opening. The opaque film is visually exposed via the transparent housing. A manufacturing method of the housing structure is also provided.

### CROSS-REFERENCE TO RELATED APPLICATION

This application claims the priority benefit of Taiwan application serial no. 106109354, filed on Mar. 21, 2017. The entirety of the above-mentioned patent application is hereby incorporated by reference herein and made a part of this specification.

### BACKGROUND

### 1. Technical Field

The disclosure relates to a housing structure and a manufacturing method thereof, and particularly relates to a housing structure of an electronic device and a manufacturing method thereof.

### 2. Description of Related Art

In the development and design of the housing structures of electronic devices, it is common to adopt an eye-catching and novel (fashionable) pattern as the main point of the design, together with a visually appealing material, to draw the consumers' attention. The pattern is normally implemented by pasting a patterned sticker on the housing structure or providing the pattern as desired during a plastic injection process of the housing structure to integrally form the pattern.

However, the sticker may be less durable (e.g., may be easily detached) during use, and providing the pattern in the plastic injection process requires additional processing to form the pattern on a mold for plastic injection, making the manufacturing cost higher. Thus, it still requires additional work for the designers to come up with a more desirable solution.

### SUMMARY

The disclosure provides a housing structure of an electronic device and a manufacturing method of the housing structure of the electronic device. By disposing an opaque film on an inner surface of a transparent housing, a sense of visual transparency is brought forth to the housing structure, and the aesthetics of the housing structure becomes more desirable.

A housing structure of an electronic device according to an embodiment of the disclosure includes a transparent housing and an opaque film. The transparent housing has an inner surface and an outer surface opposite to each other, and the transparent housing has at least one opening connecting the inner and the outer surfaces. The opaque film is attached to the inner surface by vacuuming and discharging air through the opening. The opaque film is visually exposed via the transparent housing.

A manufacturing method of a housing structure according to an embodiment includes: providing a transparent housing having at least one opening to connect an inner surface and an outer surface of the transparent housing; and attaching an opaque film to the inner surface of the transparent housing by vacuuming and discharging air through the at least one opening.

Based on the above, by disposing the opaque film on the inner surface of the transparent housing, the opaque film is visually exposed via the transparent housing, thereby bringing forth a sense of visual transparency to the housing structure of the electronic device. Accordingly, the aesthetics of the electronic device becomes more desirable. In addition, since the opaque film has the inner surface attached to the transparent housing by vacuuming, and the transparent housing has the opening connecting the inner and outer surfaces, during the vacuuming process for the opaque film, the air may be smoothly discharged through the opening. Thus, in addition to providing a force driving the opaque film toward the inner surface of the transparent housing, the air between the transparent housing and the opaque film is also removed effectively. Accordingly, a bonding strength between the transparent housing and the opaque film is reinforced.

In order to make the aforementioned and other features and advantages of the disclosure comprehensible, several exemplary embodiments accompanied with figures are described in detail below.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a flowchart illustrating a manufacturing process of a housing structure according to an embodiment of the disclosure.

FIGS. 2 to 6 are respectively schematic views illustrating structures corresponding to the flowchart of FIG. 1.

FIGS. 7A and 7B are top views respectively illustrating transparent housings according to different embodiments of the disclosure.

FIG. 8 is a partial cross-sectional view illustrating a housing structure according to yet another embodiment of the disclosure.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

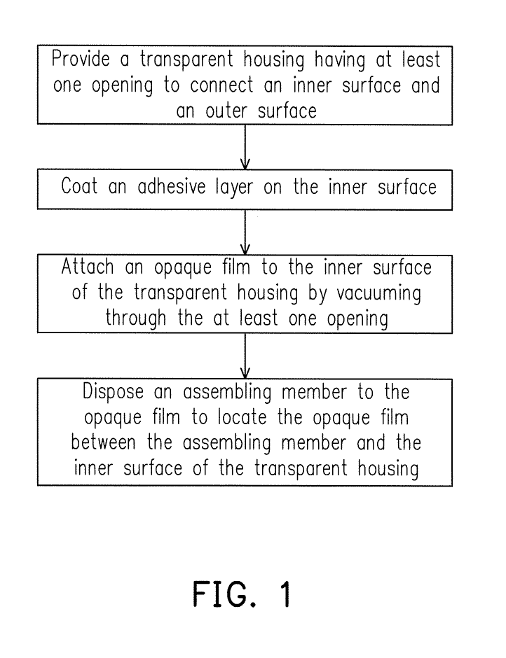

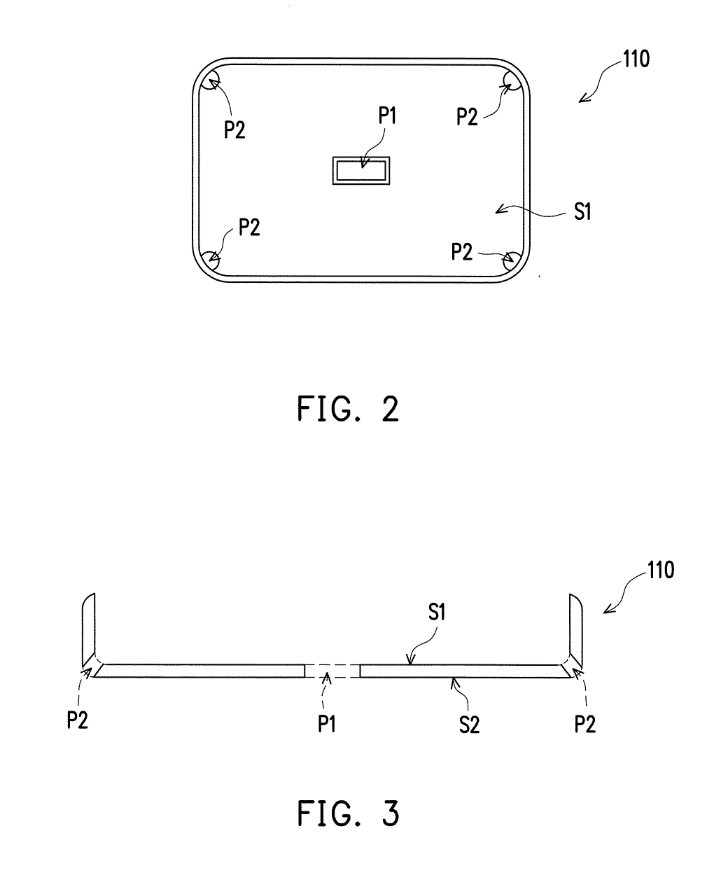

FIG. 1 is a flowchart illustrating a manufacturing process of a housing structure according to an embodiment of the disclosure. FIGS. 2 to 6 are respectively schematic views illustrating structures corresponding to the flowchart of FIG. 1. Referring to FIG. 1 together with FIGS. 2 to 6, in the embodiment, an electronic device is a laptop computer, for example, and the housing structure refers to a back cover of a display visually occupying a majority of an overall appearance of the electronic device. However, the housing structure of the disclosure is not limited thereto. In other words, the housing structure is also applicable in other well-known electronic devices such as a mobile phone or a tablet computer.

To manufacture the housing structure of the embodiment, referring to FIG. 1 together with FIGS. 2 and 3, a transparent housing 110 is firstly provided. The transparent housing 110 has an inner surface S1, an outer surface S2, and at least one opening connecting the inner surface S1 and the outer surface S2. A material of the transparent housing 110 includes a plastic material, and the transparent housing 110 is manufactured by injection molding. In addition, the opening is formed by a patching surface (shut-off surface) of a mold. In addition, the at least one opening includes a first opening P1 and a plurality of second openings P2. The first opening P1 is located at the center of the transparent housing 110. The second openings P2 are respectively located at edges or corners of the transparent housing 110. Also, as shown in FIG. 3, the second openings P2 of the embodiment are substantially located at structural turning points of the transparent housing 110. Still, in another embodiment not shown herein, the transparent housing includes the first opening located at the center only. Besides, in yet another embodiment not shown herein, the material of the transparent housing may also include glass.

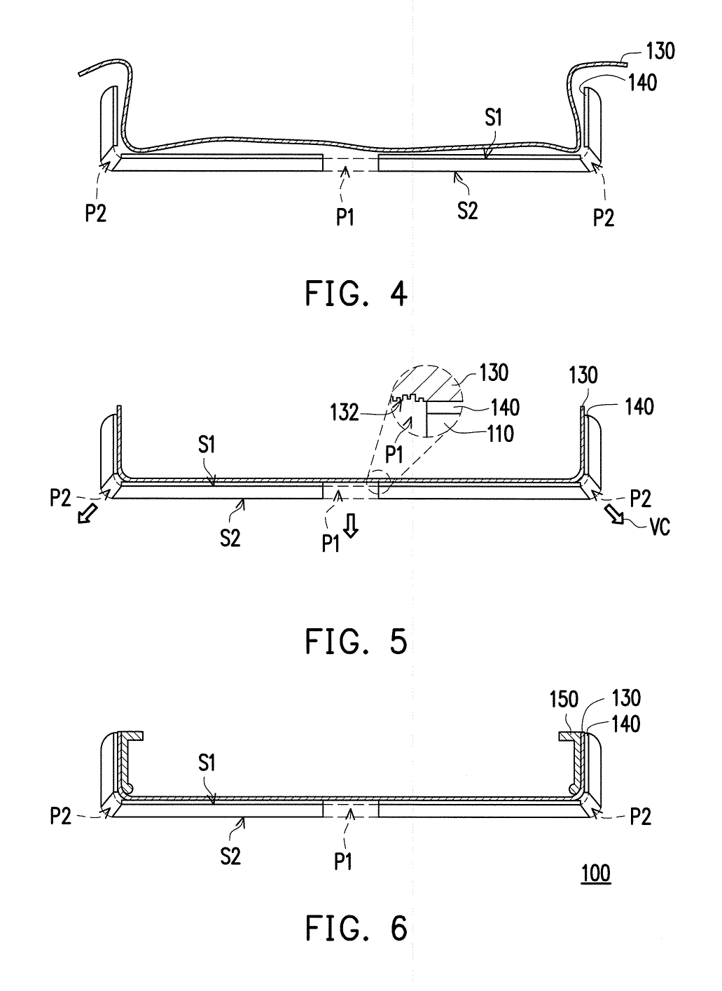

Then, referring to FIG. 1 and FIG. 4 together, an adhesive layer 140 is firstly coated on the inner surface S1 of the transparent housing 110, and then an opaque film 130 is disposed on the inner surface S1. Here, a material of the opaque film 130 may include polyethylene terephthalate (PET) that is opaque, for example. Then, referring to FIG. 1 and FIG. 5 together, the transparent housing 110 and the opaque film 130 are placed together in an enclosed space (not shown), and a vacuum condition VC is provided to attach the opaque film 130 to the inner surface S1 of the transparent housing 110. With the first opening P1 and/or the second openings P2, a path for air to be smoothly and evenly discharged is provided. Accordingly, the opaque film 130 is driven toward and attached to the inner surface S1 of the transparent housing 110. Meanwhile, the air remaining between the opaque film 130 and the adhesive layer 140 is effectively discharged. Thus, the opaque film 130 is firmly attached to the inner surface S1 of the transparent housing 110 through the adhesive layer 140.

Lastly, referring to FIG. 1 and FIG. 6 together, an assembling member 150 is provided and disposed at a side of the opaque film 130 facing away from the transparent housing 110. Hence, the opaque film 130 is located between the assembling member 150 and the transparent housing 110. Accordingly, the housing structure 100 is manufactured.

Referring to FIG. 5, in the embodiment, the opaque film 130 further includes a pattern 132, such as a microstructure imprinted on a surface of the opaque film 130, facing toward the transparent housing 110. In a state shown in FIG. 4, by aligning the pattern 132 to the first opening P1 of the transparent housing 110, the pattern 132 may be exposed out of the transparent housing 110 through the first opening P1. A position of the pattern 132 is not specifically limited. The pattern 132 may also be exposed out of the transparent housing 110 through another opening (e.g., the second opening P2), or be directly covered by a physical portion of the transparent housing 110 without an opening.

Based on the above, a sense of transparency is brought forth to the appearance of the housing structure 100 by disposing the opaque film 130 on the inner surface S1 of the transparent housing 110. Also, with intervention of the opaque film 130, electronic components in the housing structure 100 are prevented from being directly viewable. Furthermore, the pattern 132 disposed on the opaque film 130 is also effectively protected by the transparent housing 110.

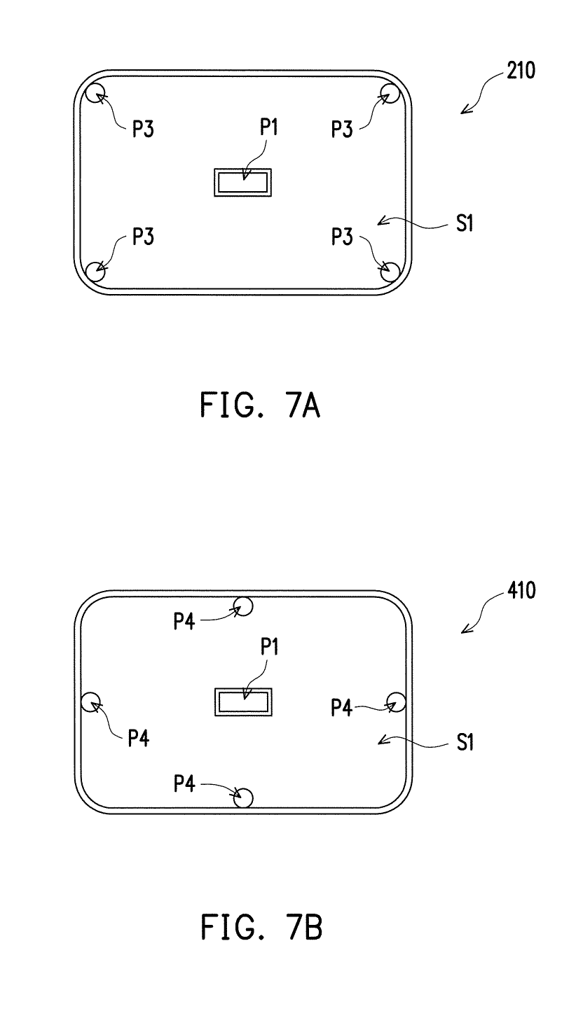

FIGS. 7A and 7B are top views respectively illustrating transparent housings according to different embodiments of the disclosure. What differs from the previous embodiment is that a transparent housing 210 in the embodiment shown in FIG. 7A has the first opening P1 and a plurality of openings P3. Similar to the second openings P2 of the previous embodiment, the third openings P3 are located at four corners of the transparent housing 210. However, what differs is that the third openings P3 are substantially completely located on the inner surface S1 instead of being located at the structural turning points. Referring to FIG. 7B, a plurality of fourth openings P4 are also completely located on the inner surface S1, instead of being located at the structural turning points. Besides, the openings P4 are located at four sides of a transparent housing 310, instead of being located at the corners. Accordingly, in order for the opaque film and the transparent housing to be combined with each other, the designer may suitably adjust the position of the opening on the transparent housing based on the position as desired and the requirements for combination.

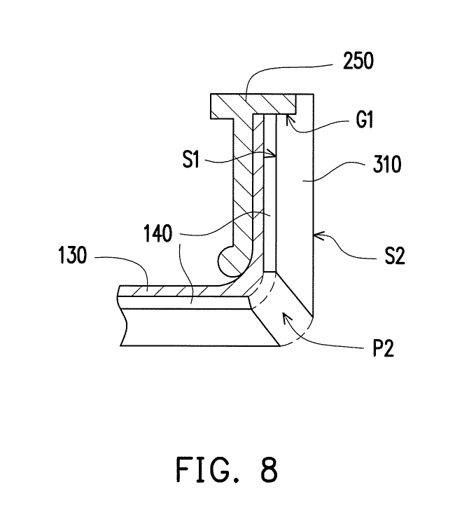

FIG. 8 is a partial cross-sectional view illustrating a housing structure according to yet another embodiment of the disclosure. What differs from the previous embodiment is that an edge of the transparent housing 310 and an assembling member 250 are fit to each other. More specifically, in the housing structure of the electronic device of the embodiment, the housing 310 is combined with another housing (not shown), so that the inner surface S1 and the another housing form an accommodating space for electronic components (such as a display) of the electronic device, the assembling member 250, and the opaque film 130 to be located in the accommodating space. A stage structure is provided on the edge of the transparent housing 310. Accordingly, when the transparent housing 310 and the another housing are combined, the assembling member 250 may be held therebetween to reinforce an assembling strength of the assembling member in the housing structure and more firmly hold and fix the opaque film 130 to the inner surface S1 of the transparent housing 310 by the assembling member 250.

In view of the foregoing, in the embodiments of the disclosure, by disposing the opaque film on the inner surface of the transparent housing, the opaque film is visually exposed via the transparent housing, thereby bringing forth a sense of visual transparency to the housing structure of the electronic device. Accordingly, the aesthetics of the electronic device becomes more desirable.

In addition to providing the visual effect, the transparent housing may further cover the pattern on the opaque film or expose the pattern only through the opening, so as to offer protection.

Moreover, the transparent housing has the first opening located at the center of the transparent housing and the second opening located on the edge of the transparent housing. The openings serve to provide a path for air to be evenly and smoothly discharged when the opaque film is attached to the transparent housing by vacuuming, so as to effectively reduce an air gap between the combined components.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims and their equivalents.

What is claimed is:

1. A housing structure of an electronic device, comprising:
a transparent housing, having an inner surface and an outer surface opposite to each other and having at least one opening connecting the inner surface and the outer surface; and
an opaque film, attached to the inner surface by vacuuming and discharging air through the at least one opening, wherein the opaque film is visually exposed via the transparent housing.

2. The housing structure as claimed in claim 1, wherein a material of the transparent housing comprises a plastic or glass material.

3. The housing structure as claimed in claim 1, wherein the at least one opening is located at the center of the transparent housing.

4. The housing structure as claimed in claim 1, wherein the at least one opening comprises a first opening and a plurality of second openings, the first opening is located at the center of the transparent housing, and the second openings are located at edges or corners of the transparent housing.

5. The housing structure as claimed in claim 4, wherein the second openings are located at structural turning points of the transparent housing.

6. The housing structure as claimed in claim 1, further comprising an assembling member disposed to the opaque film to locate the opaque film between the assembling member and the inner surface of the transparent housing.

7. The housing structure as claimed in claim 1, wherein the at least one film has a pattern, and the pattern is exposed out of the transparent housing through the at least one opening.

8. A manufacturing method of a housing structure, comprising:
providing a transparent housing having at least one opening to connect an inner surface and an outer surface of the transparent housing; and
attaching an opaque film to the inner surface of the transparent housing by vacuuming and discharging air through the at least one opening.

9. The manufacturing method of the housing structure as claimed in claim 8, further comprising:
coating an adhesive layer on the inner surface before attaching the opaque film to the transparent housing by vacuuming.

10. The manufacturing method of the housing structure as claimed in claim 8, further comprising:
disposing the assembling member to the opaque film to locate the opaque film between the inner surface and the assembling member.

11. The manufacturing method of the housing structure as claimed in claim 8, wherein the transparent housing is formed by plastic injection molding.

12. The manufacturing method of the housing structure as claimed in claim 11, wherein the at least one opening is formed by a patching surface of a mold.

13. The manufacturing method of the housing structure as claimed in claim 8, further comprising:
forming a pattern on the opaque film; and
aligning the pattern to the at least one opening when attaching the opaque film to the transparent housing by vacuuming.
